(19) United States
(12) Patent Application Publication
(10) Pub. No.: US 2016/0231097 A1
(43) Pub. Date: Aug. 11, 2016

(54) Patterned Nano-Engineered Thin Films On Flexible Substrates For Sensing Applications

(71) Applicant: THE REGENTS OF THE UNIVERSITY OF MICHIGAN, Ann Arbor, MI (US)

(72) Inventors: Jerome P. Lynch, Ann Arbor, MI (US); Andrew R. BURTON, Ann Arbor, MI (US)

(21) Appl. No.: 14/830,934

(22) Filed: Aug. 20, 2015

Related U.S. Application Data
(60) Provisional application No. 62/040,472, filed on Aug. 22, 2014.

(51) Int. Cl. G01B 7/16; H05K 1/16; H05K 3/46; H05K 3/12; H05K 1/02; H05K 1/18

(52) U.S. Cl. CPC G01B 7/20; H05K 1/028; H05K 1/185; H05K 3/4644; H05K 3/1275; H05K 1/165; G03F 7/70

(57) ABSTRACT

A sensing assembly for sensing a condition. The sensing assembly comprises a substrate and a thin-film circuit element disposed on the substrate. The thin-film circuit element is exposed to the condition and outputting an analog signal in response to the condition. The thin-film circuit element having a plurality of discrete layers operably joined together to output the analog signal.

### CROSS-REFERENCE TO RELATED APPLICATIONS

This application claims the benefit of U.S. Provisional Application No. 62/040,472, filed on Aug. 22, 2014. The entire disclosure of the above application is incorporated herein by reference.

### GOVERNMENT INTEREST

This invention was made with government support under CMMI0846256 awarded by the National Science Foundation and 70NANB9H9008 awarded by the National Institute of Standards and Technology. The Government has certain rights in the invention.

### FIELD

The present disclosure relates to patterned nano-engineered thin films on flexible substrates for sensing applications.

### BACKGROUND AND SUMMARY

This section provides background information related to the present disclosure which is not necessarily prior art. This section provides a general summary of the disclosure, and is not a comprehensive disclosure of its full scope or all of its features.

The challenges facing America's aging network of infrastructure systems require engineers to more accurately quantify the performance and health of their structures. The need for improved health assessment is growing given the vast portion of infrastructure identified as requiring repair or replacement by a recent American Society of Civil Engineers (ASCE) report that designated American infrastructure with a “D+” grade point average. Over the coming decades, demand for accurate structural health characterization is predicted to grow due to the need to adopt more cost-efficient repair and replacement strategies within severe budget constraints. The ramifications of inadequate approaches to infrastructure management can lead to catastrophes on scale with the recent the I-35 W Minneapolis bridge collapse (2007).

Contemporary sensing technologies fail to meet all of the needs of the structural management field. Structural integrity assessment in most industries is still based on visual inspection. Visual inspection is subjective, labor intensive, and may not be feasible in areas that are difficult to reach. An alternative approach is to install a structural monitoring system consisting of point sensors (i.e., sensors making a discrete, localized measurement). Point sensing provides valuable quantitative information as is needed for informed decision making; however, measurements at a single location or finite set of locations is generally insufficient for accurate damage identification. Furthermore, densification of the sensor network remains prohibitive in terms of both cost and installation complexity. A potentially more effective approach may be to seek spatial measurements over an area or volume of a structure.

The technical challenges of managing the health of critical infrastructure systems necessitate greater structural sensing capabilities. Among these needs is the ability for quantitative, spatial damage detection on critical structural components. Advances in material science have now opened the door for novel and cost-effective spatial sensing solutions specially tailored for damage detection in structures. However, challenges remain before spatial damage detection can be realized. Some of the technical challenges include sensor installations and extensive signal processing requirements.

The present teachings address these challenges by developing, in some embodiments, a patterned carbon nanotube composite thin film sensor whose pattern has been optimized for measuring the spatial distribution of strain. In some embodiments, the carbon nanotube-polymer nanocomposite sensing material is fabricated on a flexible polyimide substrate using a layer-by-layer deposition process. The thin film sensors are then patterned into sensing elements using optical lithography processes common to microelectromechanical systems (MEMS) technologies. The sensor array is designed as a series of sensing elements with varying width to provide insight on the limitations of such patterning and implications of pattern geometry on sensing signals.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIGS. 1A-1D illustrate the fabrication stages for small-scale sensing skins: FIG. 1A polyimide on glass slide; FIG. 1B CNT thin film covering PR and polyimide on slide; FIG. 1C patterned CNT sensing skin with circuit elements of thickness 10, 250, 500, 1000, and 1500 microns from left to right as fabricated and tested; and FIG. 1D polyimide substrate epoxy bonded to PVC coupon with silver colloidal paste used to attach electrodes.

FIG. 2 illustrates a schematic of the sensing assembly of the present teachings.

FIG. 3 is a schematic illustrating the potential combination of sensors designed to measure various measurands on a single flexible substrate.

FIG. 4A illustrates thin film sensors on flexible substrates with patterned copper electrodes.

FIG. 4B illustrates thin film sensors on flexible substrates with surface mount soldered circuit elements (resistors) for voltage readout.

FIGS. 5A-5B illustrate sensing skin placement and instrumentation on a steel beam-column structural specimen. FIG. 5A illustrates the location of the sensing skin on the structural system; FIG. 5B shows a close-up view of two instrumented sensing skins on the web of the steel beam.

FIGS. 6A-6B show images of patterned sensors magnified at 20× showing some limited roughness along patterned film edges.

FIGS. 7A-7F illustrate change in resistance under cyclic loading circuit elements of thickness: (a) 10 microns; (b) 250 microns; (c) 500 microns; (d) 1000 microns; (e) 1500 microns; (f) measured specimen strain using a tradition strain gage.

FIGS. 8A-8C illustrate electrical properties of circuit elements: (a) Initial resistance; (b) sheet resistance; (c) gage factor.

FIG. 9 is a photo of a patterned large-scale sensing skin designed for determining the distribution of strain in a flexural beam.

FIGS. 10A-10H illustrate voltage during the loading of the beam-column structural system: signal for thin film circuit elements located from the top (element 1) to the bottom (element 8) on the web.

FIGS. 11A-11C illustrate the response of strain gages on opposite side of web with attached sensing skins at: (a) top of web; (b) middle of web; (c) bottom of web.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

### 1. INTRODUCTION

According to the principles of the present teachings, as illustrated in the figures, a sensing assembly 10 is disclosed that provides distributed and multi-modal sensing in a wide variety of applications. It should be appreciated that although the present teachings will be discussed in connection with specific configuration, methodologies, and uses, the principles of the present teachings are applicable to a wide variety of configurations, methods, and uses. Therefore, the present teachings should not be regarded as limiting. For example, the present teachings will describe specific analog circuit elements used in connection with sensing assembly 10, however alternative circuit elements such as capacitors, inductors, resistors, sensors, and/or actuators are envisioned. Additionally, the present teachings will describe lithographic patterning and layer-by-layer deposition of layers used in connection with sensing assembly 10, however alternative patterning and deposition methods known in the art are applicable in some embodiments.

As illustrated in FIGS. 2A, 2B. and 3, in some embodiments, sensing assembly 10 can comprise a substrate 12 having one or more thin-film circuit elements 14 patterned or otherwise formed in a sequential layer process thereon. Thin-film circuit elements 14 are configured to output an analog sensing signal in response to a perceived stimulus. In some embodiments, circuit elements 14 can provide different and/or varying sensing modalities that can be electrically coupled via analog circuitry to output a derived measurement. In some embodiments, substrate 12 can be a rigid substrate or a flexible substrate. A flexible substrate can be used in applications requiring flexible sensing, such as use in connection with clothing and the like.

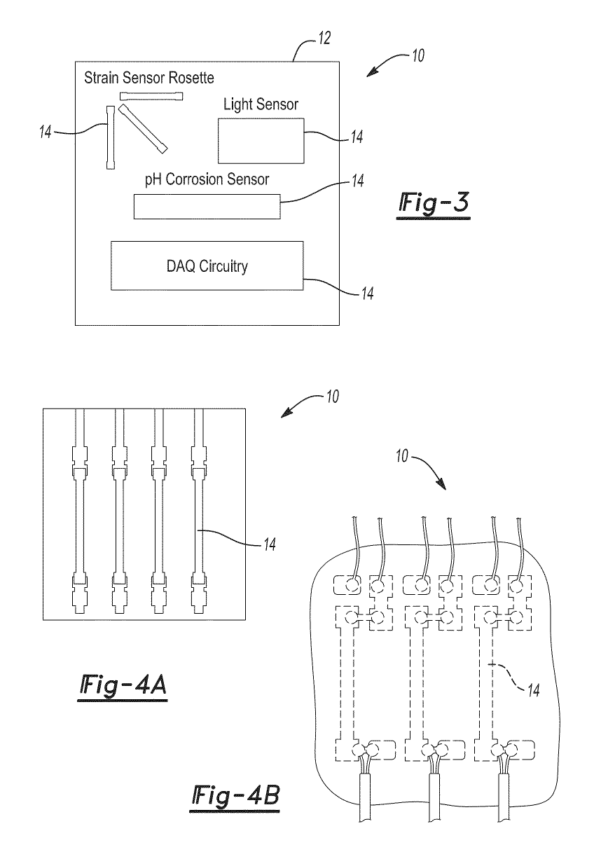

As illustrated in FIGS. 2A, 2B, and 3, in some embodiments, thin-film circuit elements 14 can comprise a wide range of analog circuit elements, such as but not limited to capacitors, inductors, resistors, sensors, and/or actuators. Each thin-film circuit element 14 is configured as a multi-layer member configured to output an analog signal. The specific configuration and method of manufacture will be described in greater detail herein. It should be understood that each circuit element 14 can comprise any one of a number of component elements, such as but not limited to nanotubes.

In fact, several potential advantages of sensing assembly 10 are bolstered by advancements in material science and nanotechnology. For instance, the discovery of carbon nanotubes has generated significant interest in many sensing communities as they have displayed a range of exceptional physical and electrical properties. These properties include increased strength, stiffness, aspect ratio, and a range of intriguing electrical characteristics. The properties of carbon nanotubes can be extended to larger applications by embedding nanotubes in a polymer matrix to form nanocomposites. This allows for the nanoengineering of thin film properties including an electrical impedance response to mechanical strain that is useful in sensing assembly 10.

One established method for the uniform fabrication of sensing assembly 10 is a layer-by-layer (LbL) deposition process which utilizes oppositely charged polyelectrolytic solutions for surface adhesion to sequentially build films. Through this process, films can be fabricated with capabilities for spatial strain sensing. However, heretofore these methods are yet to take hold as an optimal sensing solution due to the challenges of instrumenting such sensors on an actual structure. For example, prior work in LbL assembled thin films sensors deposited the film on the structure itself; this is not a scalable approach and rules out retrofit application on existing structures. Another challenge identified is the approach of creating spatial mappings of film readings. While electrical impedance tomography (EIT) has been shown to be capable of deriving film resistivity mappings from a finite set of boundary measurements, the method is computationally expensive.

Nanocomposite sensing skins can be further developed through processes commonly used in microelectromechanical systems (MEMS). Patterning CNT based composites has been investigated by a number of researchers. Of the various patterning methods attempted, optical lithography provides an effective approach for patterning polymer materials by leveraging mature cleanroom tools and processes. In using optical lithography, polymer-based thin films can be patterned with exceptional geometric control, thereby opening the door for a diverse set of applications. Additionally, the use of widely established patterning tools would allow for a relatively low cost and repeatable means to the design and production of thin films sensors. Patterning thin film sensors broadens the options available to engineers in designing thin film electronics and, more specifically, impedance-based thin film sensors.

According to the principles of the present teachings, a patterned nanocomposite sensing film is developed as the basis for future component-specific strain sensing skins. The potential for this patterning was explored through the fabrication and testing of five linear circuit elements 14 of varying width. These circuit elements 14 are patterned on a flexible polyimide substrate using conventional optical lithography. In some embodiments, the nanocomposite sensing material is deposited using the LbL fabrication process. These circuit elements 14 are designed with varying sensor widths so that the limits of the fabrication process can be assessed in the context of strain sensing. The mechanical-electrical behavior of circuit element 14 is tested using uniaxial cyclic testing on standard tensile coupon specimens.

The patterned sensing skin technology of the present disclosure is further validated using a large sensing skin designed specifically for monitoring the strain profile of a flexural structural member. In this proof-of-concept study, two sensing skins are designed, fabricated and instrumented on the web of a steel I-beam in close vicinity to a welded beam-column connection exposed to cyclic lateral loading. The present disclosure concludes with a summary of the key results and a discussion of anticipated modifications capable of further advancing the patterned sensing skin technology.

### 2. FABRICATION PROCESS

As discussed herein, sensing assembly 10 can be fabricated according to any one of a number of fabrication methods. However, for purposes of discussion, the following fabrication process is described for illustration and clarity.

2.1 Materials

In accordance with the present disclosure, PI-2525 polyimide and VM-651 polyimide adhesion promoter were obtained from HD Microsystems. Poly(vinyl alcohol) (PVA) and poly(sodium 4-styrenesulfonate) (PSS) were obtained from Sigma-Aldrich. HiPCO Single walled carbon nanotubes (SWNT) were obtained from Unidym, Inc. SPR 220-3.0 photoresist from Rohm and Haas Co. and AZ 726 developer from Clariant Corporation were used. Silver paste and copper tape were obtained from Ted Pella, Inc. All solutions were made using 18 MO cm deionized (DI) water. Chrome and copper were deposited from targets.

2.2 Optical Lithography

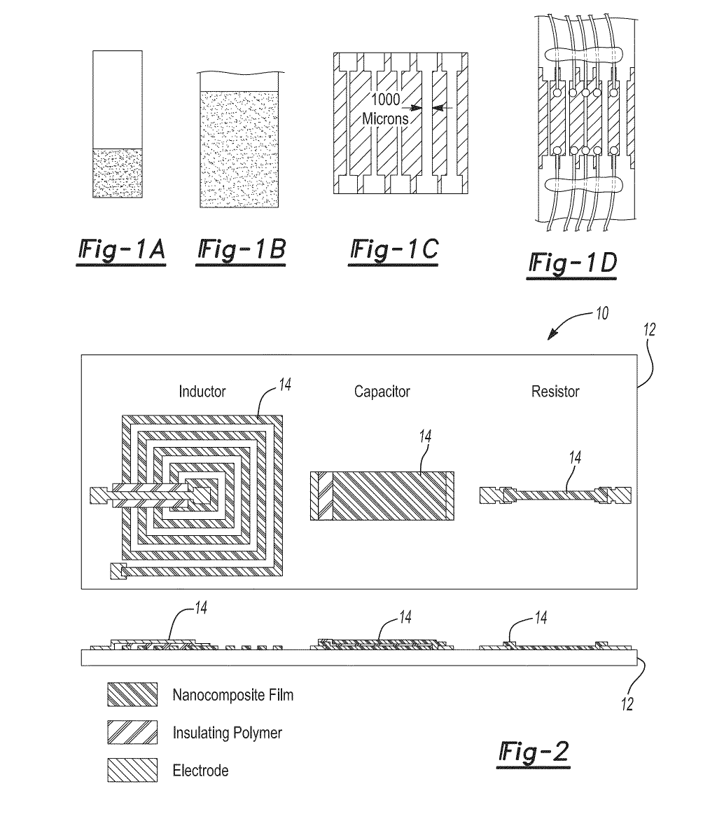

Fabrication was completed by layering thin films on a glass slide followed by detachment of the fabricated materials from the slide to yield a free-standing thin film. This process begins by spin coating adhesion promoter and then polyimide on a cleaned glass slide. The polyimide is spun at 2000 rpm resulting in a thickness of about 12 microns for each polyimide layer. Four polyimide layers are deposited to produce a polyimide film with a thickness of about 48 microns (FIG. 1A). The polyimide is cured on a hot plate by increasing the temperature from 25° C. to 300° C. at 5° C./minute and then holding the temperature at 300° C. for one hour.

After substrate fabrication, copper electrodes are patterned on the polyimide substrate 12. This process begins with the deposition of a seed layer using a Cooke electron beam evaporator. The seed layer is comprised of 800 angstroms of copper atop a 70 angstrom chromium layer for improved adhesion to the polyimide. The seed layer is patterned using conventional photolithography. Copper is then added to the patterned seed layer to complete electrode fabrication using electroplating.

Next, photoresist (PR) is patterned on the substrate 12 using optical lithography. This begins with drying and priming the polyimide for PR using an image reversal oven to apply a hexamethyldisilazane (HMDS) layer. Next, a PR layer is spun over the sample at 2000 rpm and soft baked for 90 seconds at 115° C. The PR is then exposed under a mask. A post exposure bake is completed for 90 seconds at 115° C. and then the PR is developed with AZ 726 developer for two rounds lasting 60 seconds each.

After PR is patterned on the polyimide substrate 12, the process transitions to the fabrication of the CNT thin film. The polyimide that is not covered with PR is treated with poly-l-lysine by soaking for five minutes to promote surface adhesion with the polyelectrolytes that will comprise the nanocomposite film. The copper electrode surfaces to be coated with CNT-polymer composites are cleaned immediately prior to fabrication with a sodium persulfate solution. The nanocomposite film is then deposited over the polyimide and PR by the LbL directed-assembly method (FIG. 1B).

When this is complete, the CNT composite film is lifted off of the PR covered areas by placing the samples in an acetone bath for 10 minutes and then placing this bath in a bath sonicator to apply surface energy to aid in tearing of the CNT composite film. During bath sonication, energy is applied for 30 seconds and then the samples are stationary for one minute. This process continues for approximately 10 minutes until the PR film has fully lifted from the surface.

Such patterning procedures for layer-by-layer fabricated films can be utilized to create various geometries for modular elements including sensors, resistors, capacitors, inductors, and actuators. The use of this layer-by-layer patterning with PR in planar design then allows for extended sensing and analog computing capabilities to be encoded on the very same sensing substrate 12.

The specimens fabricated by robotic LbL assembly on glass slides (termed herein as small-scale sensing skins) are patterned as 5 parallel strips roughly 2 cm long with varying thicknesses: 10 um, 250 um, 500 um, 1000 um and 1500 um (FIG. 1C). At the end of the strips are square pads where silver paste can be applied to create a wired electrical connection to a data acquisition system that is used to measure film resistances.

2.3 Layer-by-Layer Film Fabrication

The nanocomposite sensing skins are fabricated with an established layer-by-layer fabrication process. This process utilizes oppositely charged polyelectrolyte solutions to attract thin layers of each solution to the substrate surface. The substrate 12 is sequentially dipped in two solutions of opposite charge in order to build up a well-controlled, uniform thin film. The positively charged solution used here is 1.0 wt. % PVA and the negatively charged solution is 1.0 wt. % PSS. Single wall carbon nanotubes (0.1 wt. %) are non-covalently dispersed in the PSS solution using deep tip (3.178 mm tip, 150 W, 22 kHz, 90 minutes) and bath (135 W, 42 kHz, 360 minutes) sonication.

The deposition sequence for one layer of one polyelectrolyte solution consists of dipping in the solution (PSS or PVA) for four minutes followed by submersing in DI water twice for two minutes each. These steps are then followed by low pressure air drying for seven minutes and high pressure air drying for one minute. This results in the application of a single monolayer (PSS or PVA). Once this process is completed, the process is repeated using the oppositely charged polyelectrolyte solution to yield a single thin film bi-layer. The bilinear process is repeated until a film with a thickness of 50 bilayers is fabricated. The fabrication process is automated with a LbL robotic fabrication setup. Once the nanocomposite film is deposited and patterned by the lift-off process, the film is annealed for 20 minutes at 180° C. on a hot plate. Finally, the polyimide substrate is removed from the substrate by etching away a layer of glass using buffered hydrofluoric acid.

The layer-by-layer process on a flexible substrate 12 with PR patterned films allows for a compelling suite of design capabilities beyond those defined in the specific example above. Some key attributes of the proposed assembly process that sets this technology apart include:
The polymeric substrate 12 is flexible and hence conformable to multiple surfaces. In addition, the film can be fully encapsulated in the polymeric substrate material providing environmental isolation of all or parts of the substrate's thin film assemblies.
The selection of various nanoengineered materials (nanoscale fillers and polymers), processing parameters (dip time, drying methods, and polymer sequencing), and annealing processes can be used to alter film properties through control of film composition. Films can have a designed bulk resistivity to create planar resistive elements or planar polymer-based electrodes. Strain sensitivity (i.e., resistivity changes as a function of strain) can be designed by altering annealing processes and material compositions. This could be used either to enhance strain measurements or remove strain sensitivity for non-sensing modular circuit elements. Additionally, LbL films can be tailored for sensitivity to different measurands such as pH (polyaniline) or light.
Through controlled thin film assembly, capacitive and inductive elements can be assembled. Capacitive elements are assembled by layering two conductive layers with an insulative layer between. Inductive elements can be made by patterning coils in the thin film.
Patterning of copper allows for conductive elements and traces to be deposited in any spatial configuration desired. Patterned copper can also be used to leave pads for the soldering of small solid state integrated circuit chips (e.g., operational amplifiers, wireless transceiver) to be soldered to the film to aid in signal processing and to provide interfaces for collection of data from the film sensor.
Lithographic patterning of the thin films allow more than one circuit element type (sensor, resistive element, conductive element, capacitive element and inductive element) to be created. Furthermore, through appropriate sequential creation of structural and sacrificial layers, any number or combination of elements can be created on the same film. This allows multiple sensors measuring multiple parameters to be created on the same substrate. Even more novel, by combining resistive, capacitive, and inductive elements, the sensing outputs can be combined through analog circuits to process sensor outputs to output derived measurands not possible with a single sensor.
The sign of the gage factor (i.e. normalized change in resistance with strain increasing or decreasing) can be engineered via annealing processes. Differing material cross-linking and reconfiguration during annealing allows for the design of negative gage factors at lower temperatures (around 180 C) and positive gage factors at higher temperatures (above 250 C).

2.4 Larger-Scale Development

The fabrication methodology is scaled up for the development of component-specific strain sensors over larger areas. The larger-scale fabrication is completed on four inch (10.2 cm) diameter glass wafers. The process is the same as previously summarized with the exception of certain aspects of the optical lithography and nanocomposite deposition. The HDMS priming, PR spinning, and developer processes are automated with an automated optical lithography cluster tool when fabricating on a four-inch glass wafer. LbL deposition is performed by hand to accommodate the larger fabrication area. The wafer specimens were hand dipped in solution (PVA and PSS) for five minutes, rinsed with DI water, and then dried completely to fabricate each monolayer. Fabrication is otherwise completed as with the smaller glass slides. The larger-scale sensing skins are patterned in the center of the four inch glass wafers in 8 parallel strips roughly 3.5 cm long, 1.5 mm thick, and spaced 4.5 mm apart.

### 3. EXPERIMENTAL PROCEDURE

3.1 Instrumentation

Fabricated small-scale sensing skins are epoxy bonded to PVC composite specimens for uniaxial tensile testing. This requires the addition of electrodes to the patterned sensing skins. Wires are soldered to the copper bond pads patterned previously to allow for data acquisition. A digital multimeter is used to probe the attached electrodes and to determine film resistance once electrodes are dry. The multimeter is used to measure resistance and these values are collected throughout uniaxial cyclic testing. A picture of the instrumented PVC coupon is shown in FIG. 1D.

3.2 Uniaxial Cyclic Testing

The mechanical-electrical response of the sensing skins is determined using uniaxial cyclic testing on a hydraulic load frame. In this process the films are loaded for three cycles of tension-compression. The strain in the structural member is also monitored using a traditional 120Ω metal foil strain gage opposite the patterned thin film sensor. The ambient behavior of the small-scale sensing skins on the structural members is observed for five minutes prior to each test. This allows for the observation of a drift that is commonly displayed by this type of sensing film. The specimen is then loaded at a rate of 0.5 mm/min and strain data is collected throughout the loading at a 1 Hz sample rate.

3.3 Scaled Proof-of-Concept

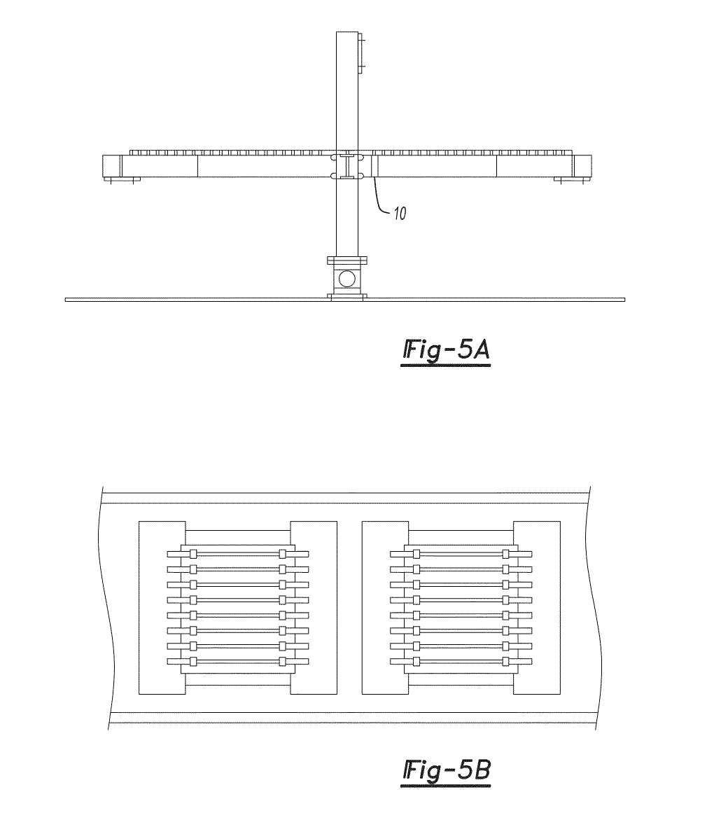

The large-scale sensing skins (FIG. 5B) are instrumented on a realistic structural system to illustrate the potential impact of patterned sensing skin technologies. These thin film sensors are epoxy bonded directly onto the surface of steel I-beam members. Once bonded to the surface of a steel beam element, copper tape and colloidal silver paste are used to create electrodes for resistance measurements. Circuit elements 14 are connected to a Wheatstone bridge with a matching resistor to produce a voltage that is low-pass filtered and amplified with a gain of 50. These boards are then connected to a wireless sensing unit that supplies a source voltage (5V) to the sensors and allows for data acquisition. Data is collected from the sensor as quasi-static loading is applied to the structural system.

For this proof-of-concept test, the sensing skins are placed on the web of a steel beam connected to a traditional welded beam-column connection (FIG. 5A). The beam-column assembly supports a concrete deck that is constructed to act in composite action with the beam. The beam-column assembly is loaded laterally at the top of the column with a hydraulic jack. The specimen is also instrumented with conventional strain gages for comparison purposes.

### 4. RESULTS

4.1 Pattern Fabrication

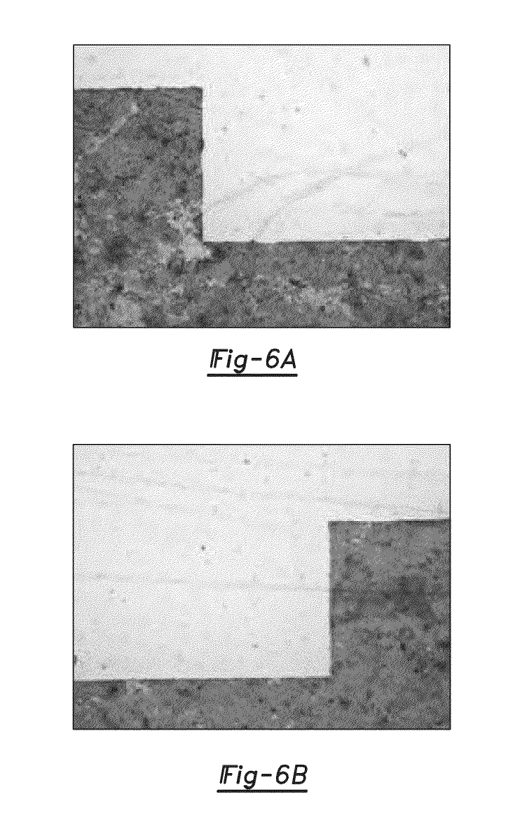

A macroscopic view of the patterned circuit elements 14 is presented in FIG. 1C. To see more clearly the quality of the patterned films, the films are imaged under a traditional optical microscope; microscope images (20 times magnification) of the edges of the nanocomposite films can be seen in FIGS. 6A and 6B. All sensor geometries attempted were patterned successfully using standard optical lithography processes. There was no noticeable deterioration of pattern quality with decreasing feature size, indicating that the lower limit on feature sizes was near that of conventional lithography materials (i.e., approximately 2 um). There was difficulty at times in achieving nanocomposite film tearing during lift-off resulting in an incomplete lift-off process but when lift-off is achieved, film geometries were defect free.

4.2 Mechanical-Electrical Response of Small-Scale Sensing Skins

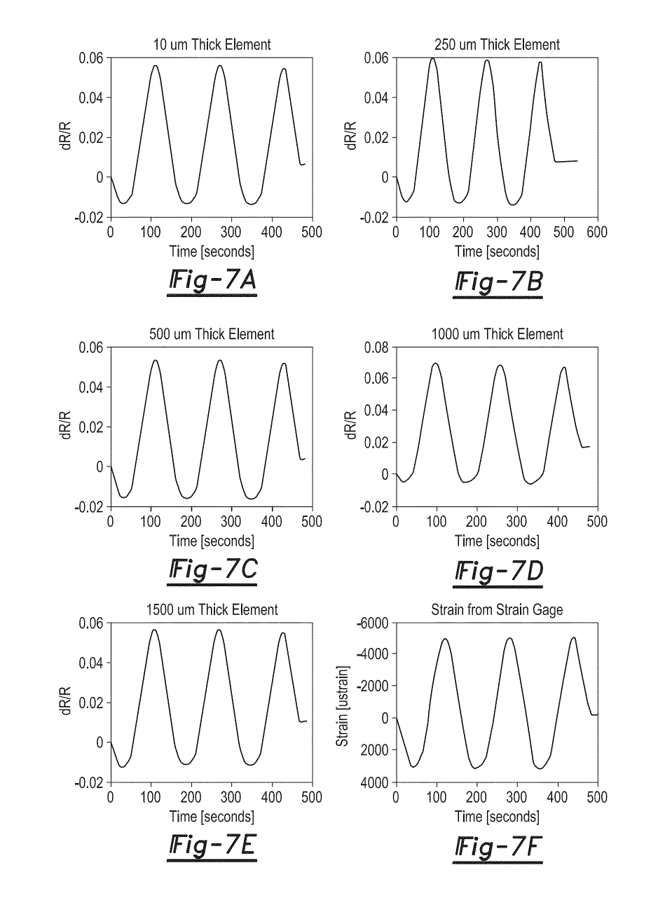

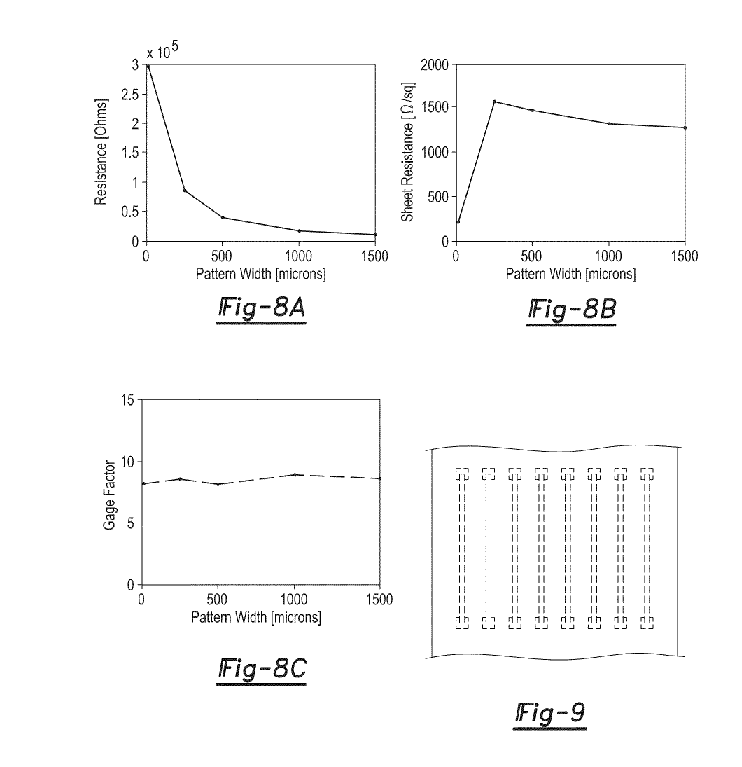

The resistance of each instrumented small-scale sensing skin was observed for five minutes prior to cyclic loading of the PVC bar. This observation displayed a rapid exponential signal decay that is commonly observed in such sensing skins. The results for each sensor under cyclic loading can be seen in FIG. 7. Here it is readily apparent that each sensor was effective in tracking the strain of the specimen (note that FIG. 7F is the measured strain using the metal foil gage). It can further be observed that all sensors have similar signals with limited noise and fairy uniform sensitivities. The initial bulk resistance, sheet resistance, and gage factors of the five sensors of varying thickness can be seen in FIG. 7. Circuit elements 14 of larger widths are more conductive as is expected for these nanocomposite films (FIG. 8A). The sheet resistance of all fabricated elements was very similar with the exception of the 10 micron thick circuit element 14 (FIG. 8B). The results also indicate a fairly uniform gage factor across all sensor geometries despite the significant variance in sensor thicknesses (FIG. 8C).

4.3 Application Proof-of-Concept

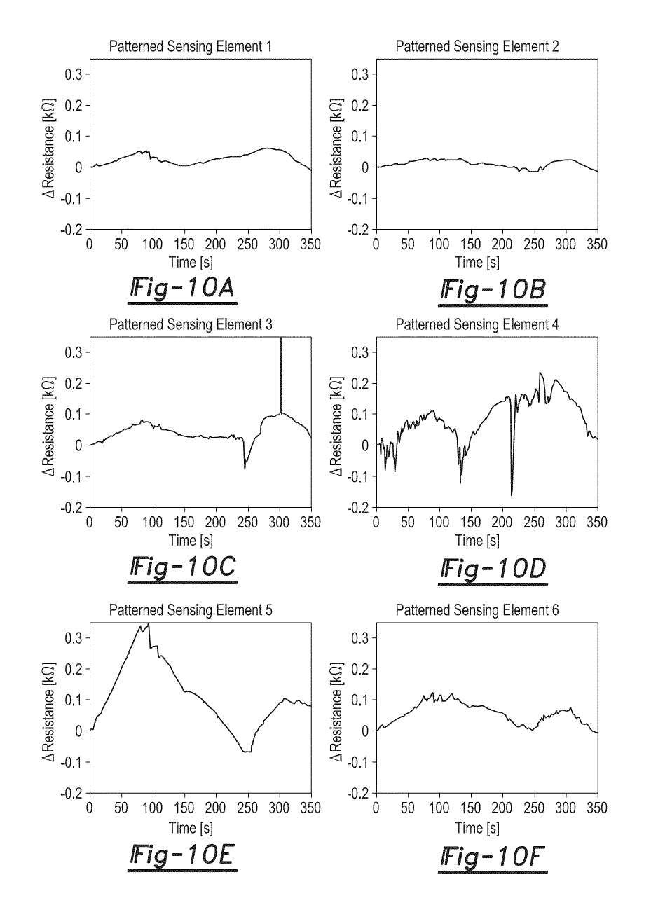

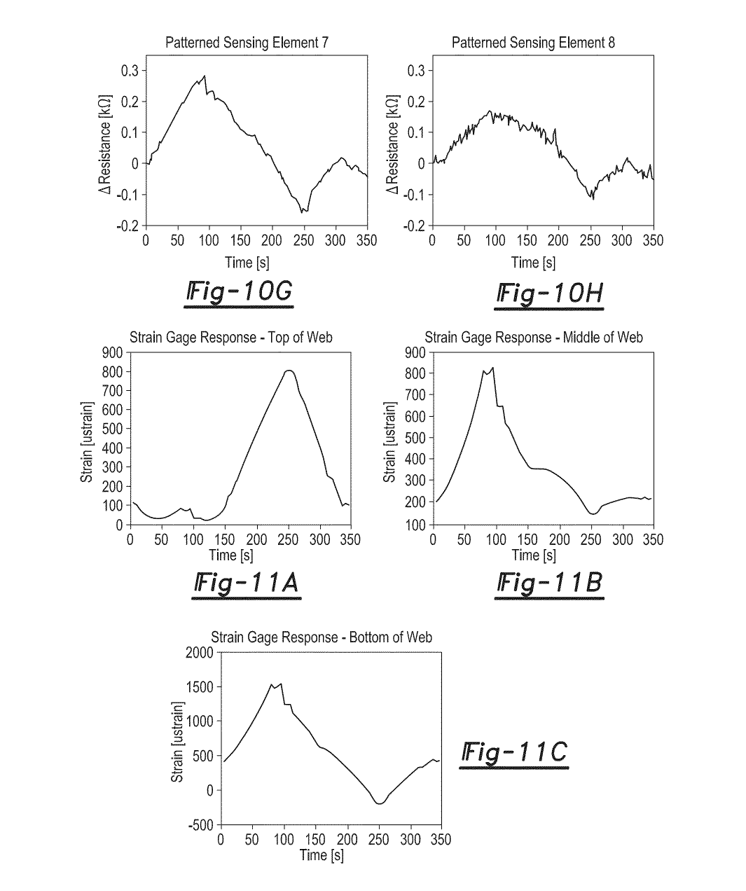

A large-scale sensing skin (FIG. 9) is fabricated to observe strain in the web of a beam responding in flexure. The sensor was instrumented on a steel beam within a beam-column structural system with a composite slab. A plot observing resistance trends in the eight sensing elements on the beam during system loading can be seen in FIG. 10. These plots correspond to one cycle of lateral inter-story drift (1.5%) response. Elements 1, 2, 5, 6, 7 and 8 track the response of the beam well when compared to the waveform collected by traditional 120Ω strain gages installed at the top, middle, and bottom of the beam on the opposite side of the web (FIG. 11). While the response is tracked well, there is some variation of the amplitude of the measured voltage signal suggesting variation in the gage factors of the films themselves. For example, elements 5 through 8 are clearly below the beam neutral axis and hence, these elements should have amplitudes increasing with depth since strain increases with depth. Discrepancy in the amplitudes may be attributed to variations in the films over their long lengths or due to local ripples in the polyimide skin when epoxy bonded to the beams. Elements 3 and 4 provided erroneous readings due to what is suspected to be faulty electrode connections. Element 3 trends properly compared to Element 1 but at 240 seconds the film response jumps; the film also outputs an unexplained spike at 300 seconds. Regardless, the results suggest the large-scale sensing skins are viable sensing platforms, but also indicate these platforms require additional investigation to improve their performance.

### 5. CONCLUSION

Nanocomposite sensing skins are patterned and tested for mechanical-electrical response. The sensor was fabricated on a flexible polyimide substrate using conventional optical lithography tools then epoxied to a PVC bar for testing. All geometries attempted were successfully patterned suggesting a limiting feature size near that of conventional lithography materials (2 um). Five small-scale sensing skin elements of varying width displayed similar sheet resistances and gage factors when instrumented and tested in uniaxial tension. The uniformity of gage factor with varying geometry was unexpected when considering the wide range of sensor geometries tested. These materials and processes were then extended to develop a component-specific sensor for monitoring the distribution of strain in a beam web. This sensor was instrumented on a beam-column structural system with a composite slab where it displayed the potential to measure the strain profile in a steel beam web. While the film elements trended well, additional work is needed to achieve a uniform gage factor of the elements. It is suspected the gage factor is varying due to the means of application of the film and not due to the film itself. For example, ripples in the film during epoxy bonding may enhance the gage factor is uncontrollable and non-repeatable ways. To remedy this potential issue, a thicker encasing layer is currently under investigation. Nonetheless, the malleability of the patterning and fabrication processes utilized provides the platform for the development of component-specific structural sensors for components of a vast range of structural systems.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A sensing assembly for sensing a condition, said sensing assembly comprising:
a substrate; and
a thin-film circuit element disposed on said substrate, said thin-film circuit element being exposed to the condition and outputting an analog signal in response to the condition, said thin-film circuit element having a plurality of discrete layers operably joined together to output said analog signal.

2. The sensing assembly according to claim 1 wherein said substrate is a rigid substrate.

3. The sensing assembly according to claim 1 wherein said substrate is a flexible substrate.

4. The sensing assembly according to claim 1 wherein at least one of said plurality of discrete layers of said thin-film circuit element is an annealed layer.

5. The sensing assembly according to claim 1 wherein said circuit element is chosen from the group consisting of inductor, capacitor, resister, sensor, and actuator.

6. The sensing assembly according to claim 1, further comprising:
a polymeric layer encapsulating said substrate and said thin-film circuit element.

7. The sensing assembly according to claim 1 wherein said plurality of discrete layers of said thin-film circuit element is made of a material configured to modify said analog signal.

8. The sensing assembly according to claim 1 wherein said plurality of discrete layers are deposited via layer-by-layer deposition and lithographic patterning to define a predetermined film composition.

9. The sensing assembly according to claim 1 wherein the condition is a strain condition and said plurality of discrete layers are configured to be responsive to the strain condition.

10. The sensing assembly according to claim 1 wherein the condition is a pH condition and said plurality of discrete layers are configured to be responsive to the pH condition.

11. The sensing assembly according to claim 1 wherein said plurality of discrete layers comprises at least a pair of conductive layers and an insulative layer disposed therebetween to provide a capacitive function.

12. The sensing assembly according to claim 1 wherein said plurality of discrete layers comprises at least one layer having coils to provide an inductive function.

13. The sensing assembly according to claim 1, further comprising conductive elements electrically coupled with said thin-film circuit element to permit electrical coupling of integrated circuit chips, said integrated circuit chips operable to receive said analog signal.

14. The sensing assembly according to claim 1 wherein said thin-film circuit element comprises a plurality of thin-film circuit elements, said plurality of thin-film circuit elements being formed simultaneously via lithographic patterning.

15. The sensing assembly according to claim 1 wherein said thin-film circuit element comprises a plurality of thin-film circuit elements, each of said plurality of thin-film circuit elements being operable to output a discrete analog signal representative of a discrete condition.

16. A method of fabricating a sensing assembly comprising:
providing a substrate;
spin coating an adhesion promoter and a polyimide on said substrate as discrete layers;
curing said polyimide layers;
patterning cooper electrodes on said polyimide;
patterning photo resist on at least a portion of said polyimide layer using optical lithography; and
removing at least a portion of said polyimide layer to form a circuit element.
